(19) United States
(12) Patent Application Publication
(10) Pub. No.: US 2011/0186924 A1
(43) Pub. Date: Aug. 4, 2011

(54) SEMICONDUCTOR DEVICE AND METHOD OF FABRICATING THE SAME

(75) Inventor: Sung Gil CHUN, Incheon (KR)

(73) Assignee: Hynix Semiconductor Inc., Incheon (KR)

(21) Appl. No.: 12/840,152

(22) Filed: Jul. 20, 2010

(30) Foreign Application Priority Data
Feb. 4, 2010 (KR) 10-2010-0010446

(51) Int. Cl. H01L 27/088; H01L 21/8234; H01L 29/78

(52) U.S. Cl. 257/331; 438/270; 257/E21.616; 257/E27.06; 257/E29.262

(57) ABSTRACT

A semiconductor device is directed to reduce a leakage current generated by parasitic field effects and increase or improve operational reliability by forming an insulating layer inside a word line. An embodiment of the present invention provides a semiconductor device comprising a gate pattern over an active region and a device isolation structure, wherein the gate pattern comprises a first gate pattern over the active region and a second gate pattern over the device isolation structure, the first and the second gate patterns having a different structure.

### CROSS-REFERENCE TO RELATED APPLICATION

Priority is claimed to Korean patent application number 10-2010-0010446, filed on Feb. 4, 2010, which is incorporated by reference in its entirety.

### FIELD OF THE INVENTION

The present invention relates to a method of manufacturing a highly integrated semiconductor apparatus, and more specifically, to a method for increasing the integration of a semiconductor apparatus including a vertical transistor and improving operational reliability and production yield of the semiconductor apparatus.

### BACKGROUND OF THE INVENTION

Generally, a semiconductor material has an electrical conductivity between a conductor and a nonconductor. Although the semiconductor shows characteristics of a nonconductor with no impurities added, addition of impurities or other manipulation can change the electric conductivity of the semiconductor and make it operate as a conductor. For example, impurities are added to the semiconductor to form a transistor. A semiconductor apparatus refers to an apparatus having various functions made of the semiconductor device. A semiconductor memory apparatus is a representative example of the semiconductor apparatus.

In many semiconductor device systems, a semiconductor memory apparatus is configured to store data generated or processed in the device. For example, if a request from a central processing unit (CPU) is received, a semiconductor memory apparatus may output data to the CPU from unit cells in the apparatus, or the apparatus may store data processed by the CPU to unit cells of an address transmitted with the request.

As storage capacities of semiconductor memory have increased, the sizes of the semiconductor memory apparatus have not increased proportionally. Thus, various elements and components used for read or write operations in a semiconductor memory apparatus have been reduced in size. Accordingly, components and elements unnecessarily duplicated in the semiconductor memory apparatus (e.g., transistors or wires) are combined or merged to decrease the area occupied by each component. Particularly, a reduction in the unit cell size included in the semiconductor memory apparatus significantly improves the degree of integration.

A typical semiconductor memory apparatus includes a plurality of unit cells each including a capacitor and a transistor. A double capacitor has also been used to temporarily store data. A transistor has been used to transmit data between a bit line and a capacitor corresponding to a control signal (word line).

The transistor has three regions including a gate, a source and a drain. The charges between the source and drain move in response to a control signal inputted to the gate. The charges between the source and the drain move through a channel region in accordance with the properties and operation of the semiconductor.

When forming a typical transistor using a semiconductor substrate, a gate is formed on the semiconductor substrate, and a source and a drain are formed by doping impurities into portions of the semiconductor substrate at both sides of the gate. However, as the data storage capacity and the degree of integration of a semiconductor memory apparatus increase, the size of each unit cell is required to shrink. That is, the design rule of a capacitor and a transistor included in the unit cell has been reduced, and thus a channel length of the cell transistor has been gradually decreased. As a result, a short channel effect and drain induced barrier lowering (DIBL) have occurred in the typical transistor, which deteriorates the operational reliability of the transistor. The above drawbacks can occur as a result of a reduction in channel length. This reduction can be overcome by maintaining a threshold voltage to allow the cell transistor to perform a normal operation. In general, as the channel length of the transistor has been made smaller, the doping concentration of impurities in a region where a channel is formed has been increased.

However, as the design rule falls below 100 nm, further increasing the doping concentration in the channel region to compensate for the reduction in the design rule increases an electric field in a storage node (SN) junction. As a result, it may cause the refresh property of the semiconductor memory apparatus to deteriorate. To overcome this drawback, a cell transistor having a three-dimensional channel structure is employed to maintain a channel length, although the design rule is reduced.

In the three-dimensional channel structure, a long channel is formed in a vertical direction. Namely, since the channel length is secured in the vertical direction although a channel width is small in a horizontal direction, the doping concentration may be reduced, and thus the deterioration of the refresh property may be minimized.

A fin transistor is a typical example of a three-dimensional channel. Particularly, a fin transistor has a double gate structure, in which a channel region is formed on a silicon substrate in a protruding shape and gates are installed on both sides of the channel region. Because the vertical channel length is longer compared to a channel length in the horizontal direction, the doping may be performed at a lower concentration. Compared with the planar gate structure, the fin structure described above can significantly increase drive current, prevent leakage current from occurring, and significantly reduce the size of the semiconductor device.

FIG. 1 is a plan view showing a conventional semiconductor device. As shown, the semiconductor device is formed over an active region 102 defined by a device isolation layer (or device isolation structure) 104 over a semiconductor substrate (not shown). Hereinafter, the semiconductor device is described in detail while referring to cross-sectional views taken along the horizontal cut plane <X> and vertical cut plane <Y>.

FIGS. 2a and 2b are cross-sectional views depicting a method for fabricating a conventional semiconductor device.

Referring to FIG. 2a, an active region 102 and a device isolation layer 104 are formed over a semiconductor substrate 100. A hard mask layer 110 is formed over the active region 102 and the device isolation layer 104. The hard mask layer 110 is then patterned (etched) through a lithography process using a mask configured to define an area reserved for a gate pattern 106. The patterned hard mask layer 110 is used as an etch mask during a process for etching the device isolation layer 104 and the active region 102 to form a recess 112.

In the cross-sectional view taken along the horizontal direction <X>, the device isolation layer 104 is etched deeper than the active region 102 due to a difference in an etch selectivity ratio between the active region 102 and the device isolation layer 104. In the cross-sectional view taken along the vertical direction <Y>, the active region formed higher than the device isolation layer 104 has a fin structure.

Referring to FIG. 2b, a gate oxide layer 108 is formed over the substrate 100 in the recess 112 in the active region 102. A conductive material is deposited in the recess 112 to form the gate pattern 106. After the gate pattern 106 is formed, the hard mask layer 110 is removed. Dopants are then implanted into the active region 102 on the both sides of the gate pattern 106 through an ion implantation process to form source/drain regions 114.

Because of a reduction in the design rule, a distance between the gate patterns 106 becomes narrower in the convention semiconductor device comprising a fin-type channel. Particularly, the gate pattern 106 formed over the device isolation layer 104 is close to the source/drain region 114 so that a parasitic field effect can occur. For example, because of a neighbor gate effect, charges in a storage node tend to leak while a cell transistor is turned off (inactive). That is, the neighbor gate effect causes an off leakage current so that dynamic refresh performance, related to refresh performance while a unit cell is under operation, gets worse. Furthermore, a passing gate effect can increase a drain-induced-barrier-lowering (DIBL) phenomenon so that static refresh performance related to a data retention capability of the unit cell also gets worse.

A method for fabricating the conventional semiconductor device described above includes forming a contact hole (not shown) exposing the active region 102 and the device isolation layer 104 between the gate patterns 106 and filling a conductive material into the contact hole to form a contact pattern (not shown). If misalignment occurs when the contact pattern is formed, the gate pattern 106 over the device isolation layer 104 may be attacked and exposed. Accordingly, an electrical short between the contact pattern and the gate pattern 106 may be incurred. These defects cause a decrease in production yield.

### SUMMARY OF THE INVENTION

An embodiment of the present invention is directed to a semiconductor device and a method for manufacturing the semiconductor device, which is configured to reduce a leakage current generated by parasitic field effects and to increase or improve operational reliability by forming an insulating layer inside a word line comprising recess gate patterns over a fin-type channel region included therein.

In accordance with an embodiment of the present invention, a semiconductor device comprises a gate pattern over an active region and a device isolation layer, wherein the gate pattern comprises a first gate pattern over the active region and a second gate pattern over the device isolation layer, the first and the second gate patterns having a different structure.

The semiconductor device further comprises a channel region having a fin structure under the gate pattern and a gate oxide layer arranged between the gate pattern and the channel region. The first gate pattern comprises a gate electrode made of conductive material, and the second gate pattern comprises plural gate electrodes made of conductive material and an insulating layer between the plural gate electrodes.

The semiconductor device further comprises source/drain regions located in the active region at both sides of the gate pattern. Herein, a junction depth of the source/drain regions is in a level of the insulating layer including one of a nitride layer and an oxide layer. The insulating layer is formed in 20% to 80% depth of the gate pattern.

In accordance with an embodiment of the present invention, a semiconductor apparatus comprises a word line including a gate pattern of saddle fin transistor and another gate pattern having gate electrodes and an insulating layer between the gate electrodes.

The gate pattern is formed over an active region and a device isolation layer, but the insulating layer is formed only over the device isolation layer. The insulating layer including one of a nitride layer and an oxide layer is formed in 20% to 80% depth of the gate pattern.

The semiconductor apparatus further comprises a word line including a lower gate and an upper gate, wherein the lower gate includes the gate pattern having a poly silicon and the upper gate includes a metal material.

In accordance with an embodiment of the present invention, a method for manufacturing a semiconductor apparatus comprises forming a gate pattern including a first gate pattern formed and a second gate pattern over an active region and a device isolation layer respectively, the first and second gate patterns having different structure.

The forming a gate pattern comprises forming a lower gate electrode in a first recess in the device isolation layer, forming an insulating layer over the lower gate electrode, forming a second recess coupled to the first recess in the active region, etching the insulating layer to expose a partial portion of the lower gate electrode, and forming an upper gate electrode coupled to the lower gate electrode.

In an embodiment, the insulating layer including a nitride layer is etched by a wet etching to expose the partial portion of the lower gate electrode. In another embodiment, the insulating layer including an oxide layer is etched by an anisotropy etching to expose the partial portion of the lower gate electrode.

The forming a gate pattern further comprises forming a first gate oxide layer at sidewalls of the active region exposed by the first recess, and forming a second gate oxide layer on the active region exposed by the second recess.

The method further comprises forming an upper gate pattern over the gate pattern. Herein, the gate pattern comprises a poly silicon and the upper gate pattern comprises a metal material.

The method further comprises forming source/drain regions through an ion implantation process on the active region exposed at both sidewalls of the gate pattern.

### BRIEF DESCRIPTION OF THE DRAWINGS

FIG. 1 is a plan view showing a conventional semiconductor device.

FIGS. 2a and 2b are cross-sectional views depicting a method for fabricating a conventional semiconductor device.

FIG. 3 is a plan view showing a semiconductor device according to an embodiment of the present invention.

FIGS. 4a and 4d are cross-sectional views depicting a method for fabricating the semiconductor device shown in FIG. 3.

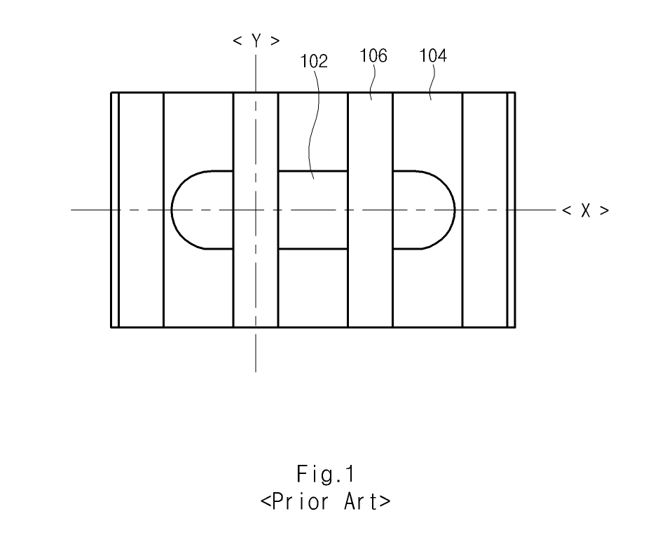

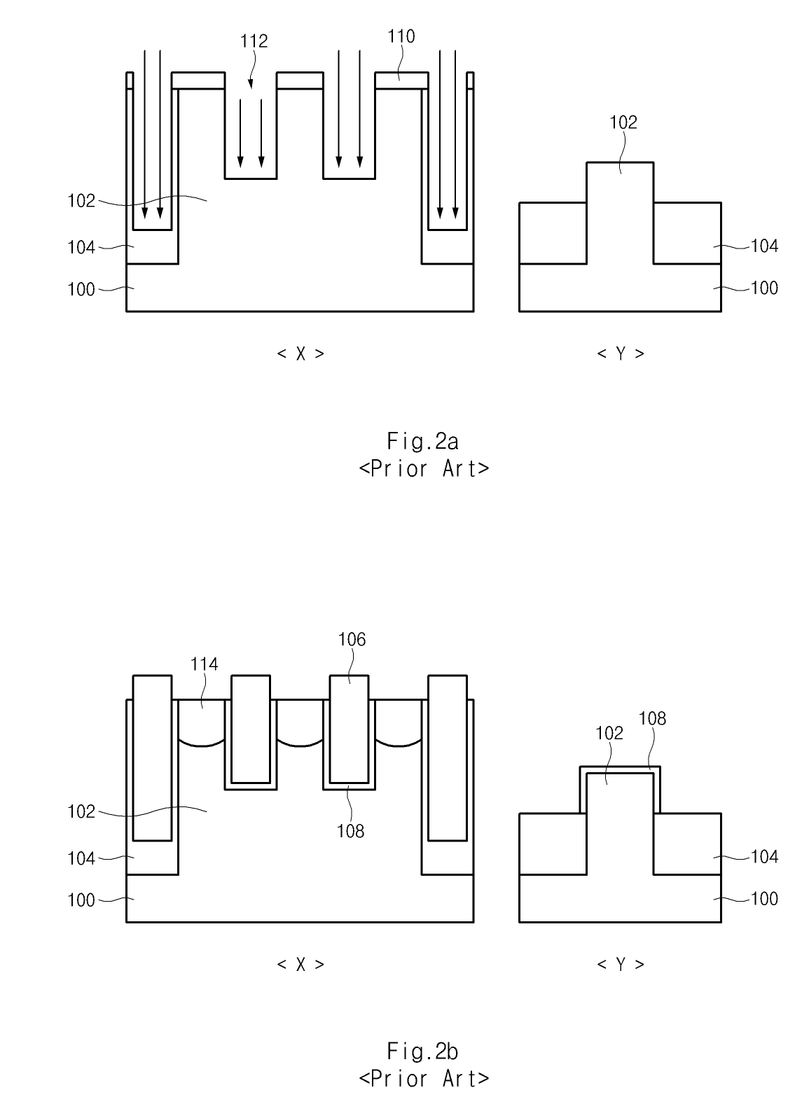

### DESCRIPTION OF SPECIFIC EMBODIMENTS

Embodiments of the present invention will be described below in more detail with reference to the accompanying drawings. The present invention may, however, be embodied in different forms and should not be limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

In an embodiment of the present invention, a word line includes two different-type gate patterns: one is a buried gate pattern formed over a device isolation layer; and the other is a recess gate pattern formed over an active region. Accordingly, a semiconductor apparatus comprising such gate patterns has the advantages of improving dynamic and static refresh performance and preventing an electrical short between a gate pattern and a contact pattern. Hereinafter, embodiments of the present invention are described with reference to the accompanying drawings.

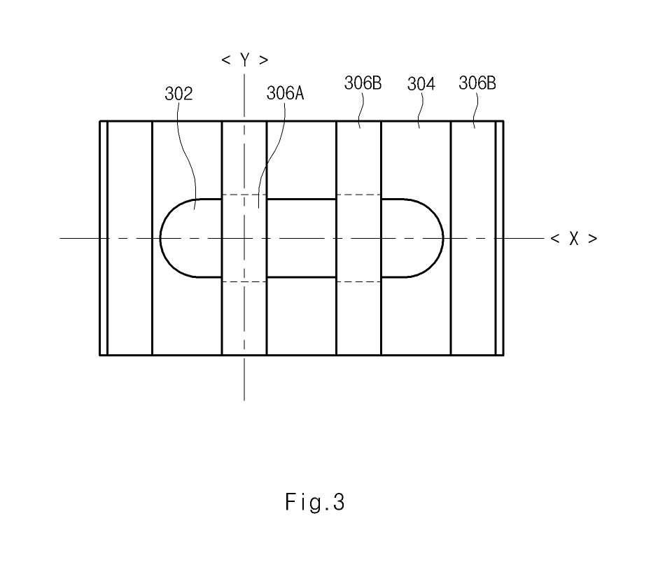

FIG. 3 is a plan view showing a semiconductor device according to an embodiment of the present invention.

As shown, an active region 302 is defined by a device isolation layer 304 over a semiconductor substrate (not shown). Gate patterns 306A and 306B are formed crossing over the active region 302. Though a plurality of active regions are formed in a semiconductor apparatus, FIG. 3 depicts one active region 302 for convenience of description.

Contrary to a conventional semiconductor device, an embodiment of the present invention provides two gate patterns 306A and 306B, each having different structure. In detail, a first gate pattern 306A formed over the active region 302 includes conductive materials, but a second gate pattern 306B formed over the device isolation layer 304 includes both a conductive material and an insulating material. Hereinafter, referring to cross-sectional views in a horizontal <X> and vertical <Y> direction, the semiconductor device is described in details.

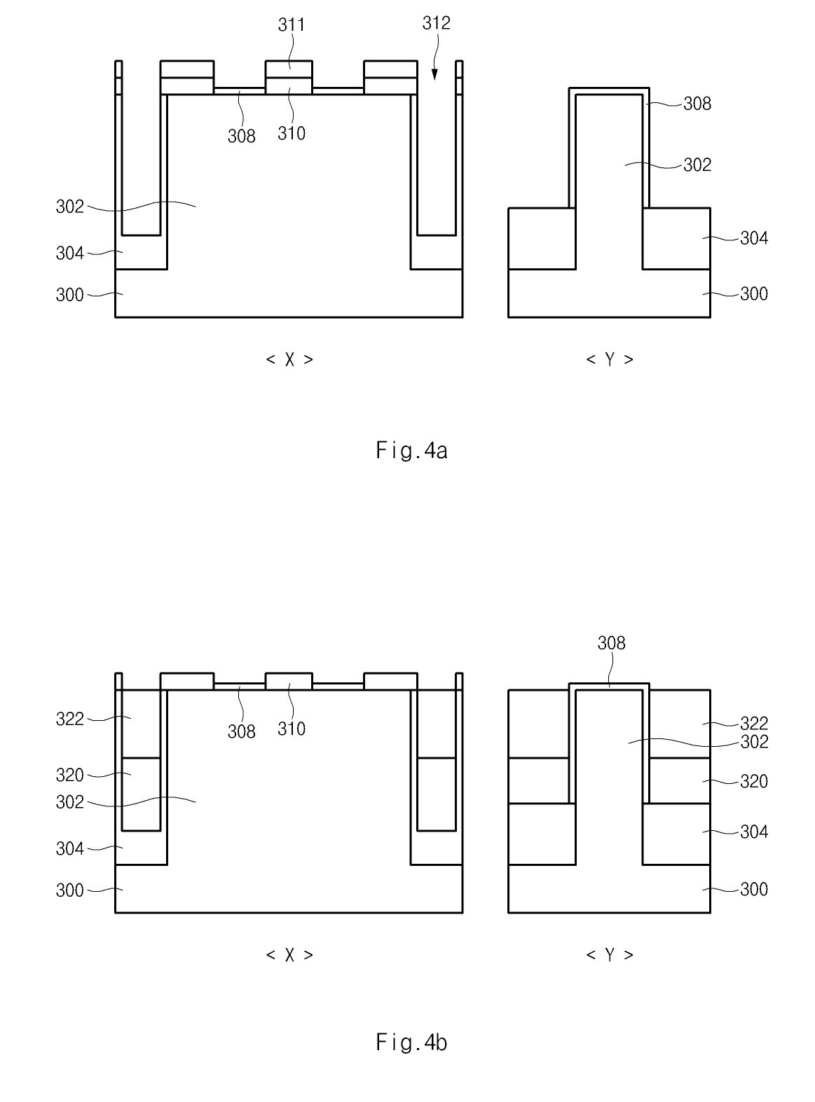

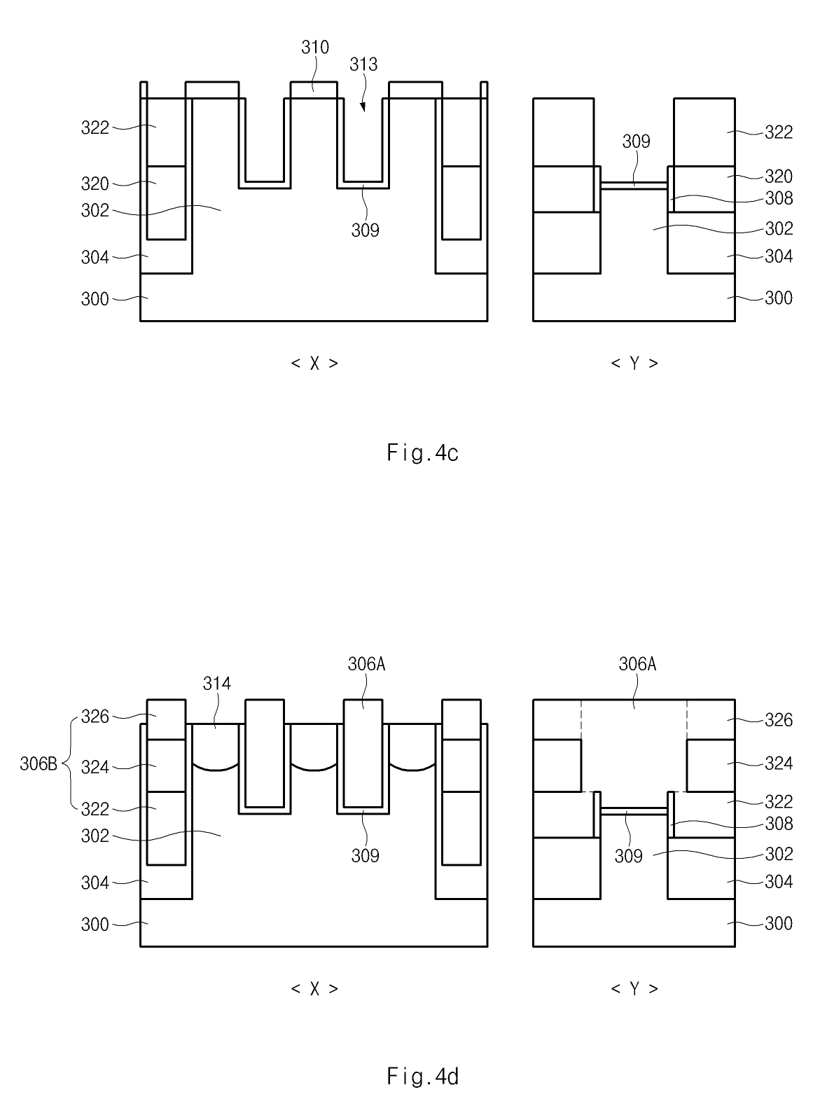

FIGS. 4a and 4d are cross-sectional views depicting a method for fabricating the semiconductor device shown in FIG. 3.

Referring to FIG. 4a, the device isolation layer 304 defining the active region 302 is formed over a semiconductor substrate 300. Then over the active region 302 and the device isolation layer 304, a first insulating layer 310 and a second insulating layer 311 are deposited in sequence. Herein, the first insulating layer 310 and the second insulating layer 311 are formed of materials with different etch selectivity. For example, if the first insulating layer 310 is formed of an oxide layer, the second insulating layer 311 may be formed of a nitride layer.

Using a mask defining an area reserved for a first gate pattern 306A and a second gate pattern 306B, the first insulating layer 310 and the second insulating layer 311 are patterned to expose the area reserved for the first and the second gate patterns 306A and 306B.

Then, the device isolation layer 304 is etched to a predetermined depth to form a first recess 312 by using the patterned first insulating layer 310 and second insulating layer 311 as an etch mask. The device isolation layer 304 may be formed of an oxide layer when the second insulating layer 311 is formed of a nitride layer so as to serve as an etch mask.

Referring to the cross-sectional view in a vertical direction <Y>, sidewalls of the active region 302 are exposed when the first recess 312 is formed. Over the exposed sidewalls of the active region 302, an oxide layer is grown through an oxidation process to form a first gate oxide layer 308.

Referring to FIG. 4b, conductive material is deposited in a lower part of the first recess 312 to form a lower gate electrode 320. Over the lower gate electrode 320 in the first recess 312, a nitride layer 322 is formed. After the nitride layer 322 is formed, an etch back process is performed onto the second insulating layer 311 and the nitride layer 322 until the first insulating layer 310 and the first gate oxide layer 308 are exposed.

Referring to FIG. 4c, the substrate 300 under the first gate oxide layer 308 is etched using the first insulating layer 310 as an etch mask, thereby forming a second recess 313. After the second recess 313 is formed, an oxide layer is grown over the substrate 300 in the second recess 313 to form a second gate oxide layer 309. Herein, the first gate oxide layer 308 and the second gate oxide layer 309 have substantially similar function and composition.

Referring to FIG. 4d, in order to expose the lower gate electrode 320 formed in the device isolation layer 304, as shown in a cross-sectional view of vertical direction <Y>, the nitride layer 322 is partially removed. A wet etching process can be employed to isotropically pattern the nitride layer 322 as shown in the cross-sectional view <Y> of FIG. 4d. An anisotropic etching process also can be employed to etch sidewalls of the nitride layer 322 in the device isolation layer 304, thereby exposing the lower gate electrode 320 under the nitride layer 322. Over the active region 302 and the device isolation layer 304, conductive material is deposited and then subject to a planarization process using the first insulating layer 310 as a mask to form the first gate pattern 306A and a upper gate electrode 324. Then, the first insulating layer 310 is removed. Accordingly, the first gate pattern 306A is formed in the active region 302. The second gate pattern 306B (formed of a stack pattern of the lower gate electrode 320), the nitride layer 322 and the upper gate electrode 324 are formed in the device isolation layer 304. The first gate pattern 306A is a recess-type gate pattern and the lower gate electrode 320 of the second gate pattern 306B is a buried-type gate pattern.

In the above-described embodiment, as shown in the cross-sectional view <Y> of FIG. 4d, the lower gate electrode 320 and the upper gate electrode 324 are electrically connected to each other in the active region 302 by the first gate pattern 306A. However, the lower gate electrode 320 and the upper gate electrode 324 are electrically isolated from each other in the device isolation layer 304. In another embodiment, an oxide layer may be used instead of the nitride layer 322. In a case where an oxide layer is used instead of the nitride layer 322, an anisotropic etching process instead of a wet etching process may be performed to pattern the oxide layer.

It is desirable that the nitride layer 322 between the lower gate electrode 320 and the upper gate electrode 324 is formed at substantially the same level as source/drain regions 314. Assuming that the total height of second gate pattern 306B is 1, the height of the lower gate electrode 320, the nitride layer 322, and the upper gate electrode 324 can be formed with a ratio of about 0.2:0.6:0.2. For example, if the bottom of the second gate pattern 306B is formed as deep as about 1200 to 1800 Å (measuring from a top of the semiconductor substrate 300), the nitride layer 322 can be formed at a level starting from about 240˜360 Å and ending at about 940˜4440 Å (measuring from the top of the substrate 300). After the first and second gate patterns 306A and 306B are formed, an ion implantation process is performed on the substrate 300 in the active region 302 to form the source/drain region 314. Herein, an ion implantation energy determines a depth level at which the source/drain region 314 is formed. It is desirable to form the source/drain region 314 at the same level in depth as the nitride layer 322.

Further, in another embodiment of the present invention, a word line in the active region 302 can be formed of a multi-layer gate. In that case, the first gate pattern 306A forms a lower gate, and an additional gate would be formed over the first gate pattern 306A as an upper gate. In the same manner, an additional gate can be formed over the second gate pattern 306B. Herein, for example, the first and second gate patterns 306A and 306B serving as the lower gates can be formed of poly silicon, and the additional upper gate can be formed of Titanium, Tungsten, Aluminum, and the like.

As above described, in an embodiment of the present invention, the semiconductor device may include two different types of gate patterns: one is a recess gate pattern formed in an active region; and the other is a buried gate pattern formed in a device isolation layer. Accordingly, dynamic refresh performance and static refresh performance both can be improved at the same time.

Since the present invention has a buried-type gate in a device isolation layer, a neighbor gate effect can be decreased by about 35%. At the same time, a dynamic refresh performance is also improved.

Furthermore, according to the present invention, the insulating layer (nitride layer 322) formed over a buried gate in the device isolation layer 304 can reduce a passing gate effect by as much as about 40% and reduce GIDL. Thus, static refresh performance can be improved.

Moreover, the insulating layer (nitride layer 322) can effectively prevent an electrical short between a contact pattern for the source/drain region 314 and the buried gate pattern (the lower gate electrode 320) because the insulating layer covers and protects the buried gate pattern from being exposed when a contact hole defining the contact pattern is formed.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a first gate pattern formed in an active region, the active region defined by a device isolation structure;
a second gate pattern formed in the device isolation structure, the second gate pattern being different that the first gat pattern; and
a source/drain region formed in the active region adjacent to the first gate pattern.

2. The semiconductor device according to claim 1, wherein the first gate pattern is a recess gate pattern and the second gate pattern is a buried gate pattern, the device further comprising:
a first three-dimensional fin channel formed under the recess gate pattern;
a first gate oxide layer arranged between the recess gate pattern and the first three-dimensional fin channel;
a second three-dimensional fin channel formed under the buried gate pattern; and
a second gate oxide layer arranged between the buried gate pattern and the second three-dimensional fin channel.

3. The semiconductor device according to claim 1, wherein the first gate pattern is a recess gate pattern and the second gate pattern is a buried gate pattern, the device further comprising:
an upper gate pattern formed over the buried gate pattern; and
an insulating layer formed between the buried gate pattern and the upper gate pattern,
wherein the buried gate pattern and the upper gate pattern are electrically isolated from each other in the device isolation structure by the insulating layer, and electrically coupled with each other in the active region through the recess gate pattern.

4. The semiconductor device according to claim 1, wherein the source/drain region is formed in the active region at both sides of the recess gate pattern.

5. The semiconductor device according to claim 3, wherein the source/drain region is formed at the substantially same depth as the insulating layer.

6. The semiconductor device according to claim 3, wherein the insulating layer has a thickness that is 20% to 80% of the total thickness of a stack pattern including the buried gate pattern, the insulating layer and the upper gate pattern.

7. A semiconductor device, comprising:
a first three-dimensional saddle-type fin transistor formed in an active region, the first fin transistor including a first gate pattern; and
a word line formed in the active region and a device isolation structure, the device isolation structure is adjacent to and defines the action region, the word line including the first gate pattern and a second gate pattern,
wherein the first gate pattern includes a recess gate electrode, and
wherein the second pattern includes a buried lower gate electrode, an upper electrode formed over the lower gate electrode and an insulating layer formed between the buried lower gate electrode and the upper gate electrode.

8. The semiconductor device according to claim 7, wherein the first gate pattern does not include the insulating layer.

9. The semiconductor device according to claim 7, wherein the insulating layer including any of a nitride layer and an oxide layer, and the insulating layer has a thickness that is 20% to 80% of the total vertical extension of the second gate pattern.

10. The semiconductor device according to claim 7, wherein the first fin transistor further comprising a first additional gate pattern formed over the first gate pattern to form a first multi-layered gate pattern.

11. A method for manufacturing a semiconductor device, comprising:
forming a first gate pattern including a recess gate electrode in an active region of a substrate; and
forming a second gate pattern including a buried gate electrode in a device isolation structure of the substrate, the device isolation structure being adjacent to and defining the active region.

12. The method according to claim 11, wherein the steps of forming the first and the second gate patterns comprises:
forming the buried gate electrode in a first trench in the device isolation structure;
forming an insulating layer over the buried gate electrode;
forming a second trench in the active region;
patterning the insulating layer on a sidewall of the second trench to form a third trench exposing the buried gate electrode;
forming the first gate pattern having a recess shape in the third trench; and
forming an upper gate electrode over the insulating layer to obtain the second gate pattern,
wherein the buried electrode and the upper electrode are electrically coupled with each other in the active region via the first gate pattern, and the buried electrode and the upper electrode are electrically isolated from each other in the device isolation structure by the insulating layer.

13. The method according to claim 12, wherein the insulating layer includes a nitride layer, and
wherein the insulating layer is patterned using a wet etching process to form the third trench.

14. The method according to claim 12, wherein the insulating layer includes an oxide layer, and
wherein the insulating layer is patterned using an anisotropy etching process to form the third trench.

15. The method according to claim 12, further comprising:
forming a first gate oxide layer over the substrate exposed by the first trench; and
forming a second gate oxide layer over the substrate exposed by the second trench.

16. The method according to claim 11, further comprising:
forming a first additional gate pattern over the first gate pattern; and
forming a second additional gate pattern over the second gate pattern.

17. The method according to claim 15, wherein the recess gate electrode includes a poly silicon and the first additional gate pattern includes a metal layer.

18. The method according to claim 11, further comprising forming a source/drain region in the active region using an ion implantation process, wherein the source/drain region is adjacent to the recess gate electrode.
